(19) United States
(12) Patent Application Publication
(10) Pub. No.: US 2026/0262551 A1
(43) Pub. Date: Sep. 3, 2026

(54) INTEGRATED ELECTRICAL AND OPTICAL INTERPOSER FOR INTERCONNECTION OF MULTIPLE ELECTRONIC AND PHOTONIC CHIPS

(71) Applicant: PsiQuantum, Corp., Palo Alto, CA (US)

(72) Inventors: Kishor DESAI, Fremont, CA (US); Himani KAMINENI, Ballston Spa, NY (US); Nathan A. NUTTALL, Castaic, CA (US); Vijay SUKUMARAN, San Jose, CA (US)

(21) Appl. No.: 19/156,031

(22) PCT Filed: Feb. 14, 2024
(86) PCT No.: PCT/US2024/015677

§ 371 Date: Aug. 13, 2025

Related U.S. Application Data
(60) Provisional application No. 63/445,580, filed on Feb. 14, 2023.

(51) Int. Cl. H10W 90/20; G02B 6/42; H10W 70/60; H10W 70/652; H10W 70/654; H10W 72/00; H10W 90/00; H10W 90/10; H10W 90/26

(52) U.S. Cl. CPC H10W 90/295; G02B 6/4245; G02B 6/4283; H10W 70/611; H10W 70/652; H10W 70/654; H10W 72/07536; H10W 90/10; H10W 90/26; H10W 90/401; H10W 90/753; H10W 90/755; H10W 90/792; H10W 90/794

(57) ABSTRACT

A hybrid electronic/photonic device includes a substrate, a first electronic/photonic integrated circuit mounted on the substrate, a second electronic/photonic integrated circuit mounted on the substrate, and an electrical coupler electrically connecting the first electronic/photonic integrated circuit to the second electronic/photonic integrated circuit. At least a portion of the electrical coupler is supported by the substrate.

### PRIORITY

This application claims the benefit of priority from U.S. Provisional Application Ser. No. 63/445,580, filed on Feb. 14, 2023, which is incorporated herein by reference in its entirety.

### TECHNICAL FIELD

Embodiments herein relate generally to cryogenic photonic and electronic chip assemblies used for quantum computing (QC) applications, and more specifically to cryogenic electrical connectors used to connect electronic and photonic dies to one another.

### BACKGROUND

A cryostat is a device that is used to maintain cryogenic temperatures (e.g., 120°K or less) for objects or materials located within the cryostat. Cryostats have been used for a number of applications in which cryogenic temperatures are desirable and/or necessary. For example, many types of quantum computing (QC) systems require quantum processing operations to be performed at extremely low temperatures. A cryostat may be used to house components of the QC system used to perform quantum processing operations such that these components may be maintained within a specified cryogenic temperature range.

### SUMMARY

According to one embodiment, a hybrid electronic/photonic device includes a substrate, a first electronic/photonic integrated circuit mounted on the substrate, a second electronic/photonic integrated circuit mounted on the substrate, and an electrical coupler electrically connecting the first electronic/photonic integrated circuit to the second electronic/photonic integrated circuit. At least a portion of the electrical coupler is supported by the substrate.

According to a further embodiment, a method of forming an electronic/photonic device comprises mounting a first electronic/photonic integrated circuit on a substrate; mounting a second electronic/photonic integrated circuit the substrate; and electrically connecting the first electronic/photonic integrated circuit to the second electronic/photonic integrated circuit using an electrical coupler, wherein at least a portion of the electrical coupler is supported by the substrate.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1A is a simplified schematic diagram illustrating an optical switch, according to some embodiments.

FIG. 1B is an illustration of a user interfacing with a hybrid quantum computing device, according to some embodiments.

FIG. 2A is a top view of a hybrid electronic/photonic device that may form a sub-system of a hybrid computing system, according to some embodiments.

FIG. 2B is a vertical cross-sectional view of a first portion of the hybrid electronic/photonic device including die stacks, according to some embodiments.

FIG. 2C is a vertical cross-sectional view of the first portion of the hybrid electronic/photonic device in which the die stacks have an alternative configuration, according to some embodiments.

FIG. 2D is a vertical cross-sectional view of a second portion of the hybrid electronic/photonic device, according to some embodiments.

FIG. 3 is an enlarged vertical cross-sectional view of a portion of the hybrid electronic/photonic device of FIG. 2D including a first connector, according to some embodiments.

FIG. 4A is a top view of a further hybrid electronic/photonic device that may form a sub-system of a hybrid computing system, according to some embodiments.

FIG. 4B is a vertical cross-sectional view of a first portion of the hybrid electronic/photonic device including die stacks including electronic and photonic dies, according to some embodiments.

FIG. 4C is a vertical cross-sectional view of the first portion of the hybrid electronic/photonic device in which the electronic and photonic dies have an alternative configuration, according to some embodiments.

FIG. 4D is a vertical cross-sectional view of a second portion of the hybrid electronic/photonic device in which an electrical coupler includes a portion formed along a surface of a photonic interposer, according to some embodiments.

FIG. 4E is a vertical cross-sectional view of the second portion of the hybrid electronic/photonic device in which the electrical coupler includes one or more redistribution layers, according to some embodiments.

FIG. 4F is a vertical cross-sectional view of the second portion of the hybrid electronic/photonic device in which the electrical coupler includes one or more redistribution layers and electrically conductive wires, according to some embodiments.

FIG. 5A is a top view of an enlarged portion of the hybrid electronic/photonic device of FIG. 4A, according to some embodiments.

FIG. 5B is a vertical cross-sectional view of a portion of a redistribution layer of FIG. 5A having a single conductive element, according to some embodiments.

FIG. 5C is a vertical cross-sectional view of a portion of a further redistribution layer having two conductive elements, according to some embodiments.

FIG. 5D is a further vertical cross-sectional view of the redistribution layer of FIG. 5C, according to some embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

Reference will now be made in detail to embodiments, examples of which are illustrated in the accompanying drawings. In the following detailed description, numerous specific details are set forth to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The following description, for purpose of explanation, is described with reference to specific embodiments. However, the illustrative discussions that follow are not intended to be exhaustive or to limit the scope of the claims to the precise forms disclosed. Many modifications and variations are possible in view of the above teachings. The embodiments were chosen to best explain the principles underlying the claims and their practical applications, to thereby enable others skilled in the art to best use the embodiments with various modifications as are suited to the particular uses contemplated.

Embodiments of the present disclosure provide electrical couplers that may be used at cryogenic temperatures. In one embodiment, the electrical couplers include materials having thermal expansion coefficients that are matched to other components, such as electrical interposers, to which they are mechanically coupled. As such, the embodiment electrical couplers may avoid degradation and damage due to thermal expansion mismatch that may otherwise occur if electrical couplers designed for room temperature use are mechanically coupled to the electrical interposers.

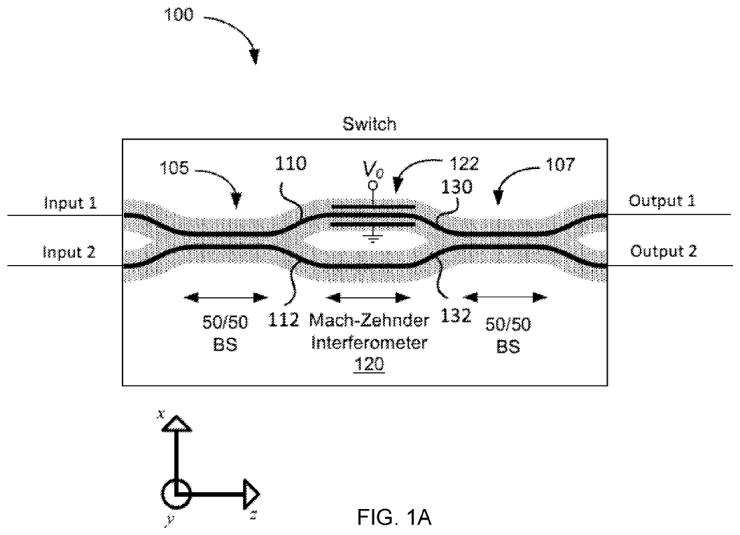

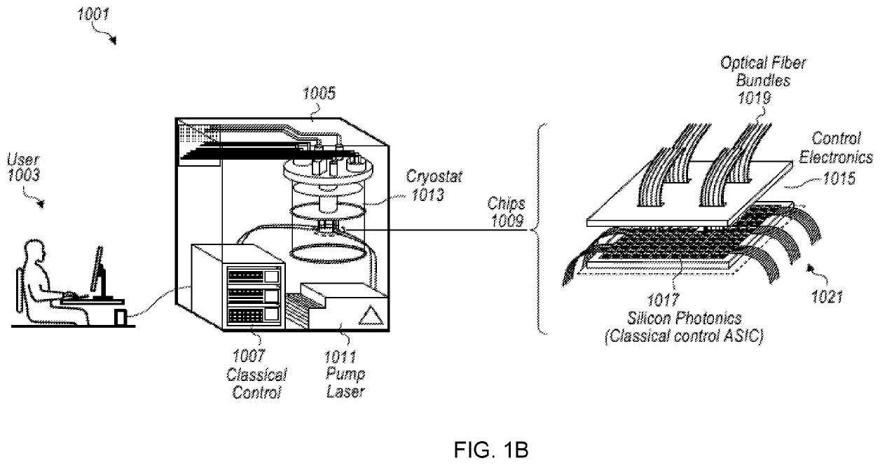

FIG. 1A is a simplified schematic diagram illustrating an optical switch according to an embodiment of this disclosure. Referring to FIG. 1A, electro-optic switch 100 includes two inputs: Input 1 and Input 2 as well as two outputs: Output 1 and Output 2. As an example, the inputs and outputs of the electro-optic switch 100 can be implemented as optical waveguides operable to support single mode or multimode optical beams. As an example, the electro-optic switch 100 can be implemented as a Mach-Zehnder interferometer integrated with a set of 50/50 beam splitters 105 and 107, respectively. As illustrated in FIG. 1A, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112.

Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage Vo can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1A, it will be appreciated that both arms of the Mach-Zehnder interferometer can include phase adjustment sections.

As illustrated in FIG. 1A, electro-optic switch technologies, in comparison to all-optical switch technologies, utilize the application of the electrical bias (e.g., V₀ in FIG. 1A) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1A, embodiments of this disclosure are not limited to this particular switch architecture and other phase adjustment devices are included within the scope of this disclosure, including ring resonator designs, Mach-Zehnder modulators, generalized Mach-Zehnder modulators, and the like. One of ordinary skill in the art would recognize many variations, modifications, and alternatives.

In some embodiments, the optical phase shifter devices described with respect to FIG. 1A above may be utilized within a quantum computing system, such as the hybrid quantum computing system shown in FIG. 1B. Alternatively, these optical phase shifter devices may be used in other types of optical systems. For example, other computational, communication, and/or technological systems may utilize photonic phase shifters to direct optical signals (e.g., single photons or continuous wave (CW) optical signals) within a system or network, and phase shifter architectures described herein may be used within these systems, in various embodiments.

FIG. 1B is a simplified system diagram illustrating incorporation of an electro-optic switch with a prior art cryostat into a hybrid quantum computing system, according to some embodiments. In order to operate at low temperatures, for example liquid helium temperatures, embodiments of this disclosure integrate the electro-optic switches discussed herein (e.g., see FIG. 1A) into a system that includes cooling systems. Thus, embodiments of this disclosure provide an optical phase shifter that may be used within a hybrid computing system of the type illustrated in FIG. 1B. The hybrid computing system 1001 includes a user interface device 1003 that is communicatively coupled to a hybrid quantum computing (QC) sub-system 1005. The user interface device 1003 may be any type of user interface device, for example, a terminal including a display, keyboard, mouse, touchscreen, and the like. In addition, the user interface device may itself be a computer such as a personal computer (PC), laptop, tablet computer, etc.

In some embodiments, the user interface device 1003 provides an interface with which a user can interact with the hybrid QC subsystem 1005. For example, the user interface device 1003 may run software, such as a text editor, an interactive development environment (IDE), command prompt, graphical user interface, and the like so that the user can program, or otherwise interact with, the QC subsystem to run one or more quantum algorithms. In other embodiments, the QC subsystem 1005 may be pre-programmed and the user interface device 1003 may simply be an interface where a user can initiate a quantum computation, monitor the progress, and receive results from the hybrid QC subsystem 1005. Hybrid QC subsystem 1005 may further include a classical computing system 1007 coupled to one or more quantum computing chips 1009. In some examples, the classical computing system 1007 and the quantum computing chip 1009 can be coupled to other electronic components, e.g., pulsed pump laser 1011, microwave oscillators, power supplies, networking hardware, etc.

The quantum computing chips 1009 may be housed within a cryostat, for example, cryogenic device 1013. In some embodiments, each of the quantum computing chips 1009 can include one or more constituent chips, e.g., hybrid electronic chip 1015 and integrated photonics chip 1017. The photonics chip 1017 may include the electro-optic switch 100 (e.g., an interferometer) shown in FIG. 1A. Signals can be routed on- and off-chip any number of ways, e.g., via optical interconnects (e.g., optical fiber bundles) 1019 and via other electronic interconnects 1021.

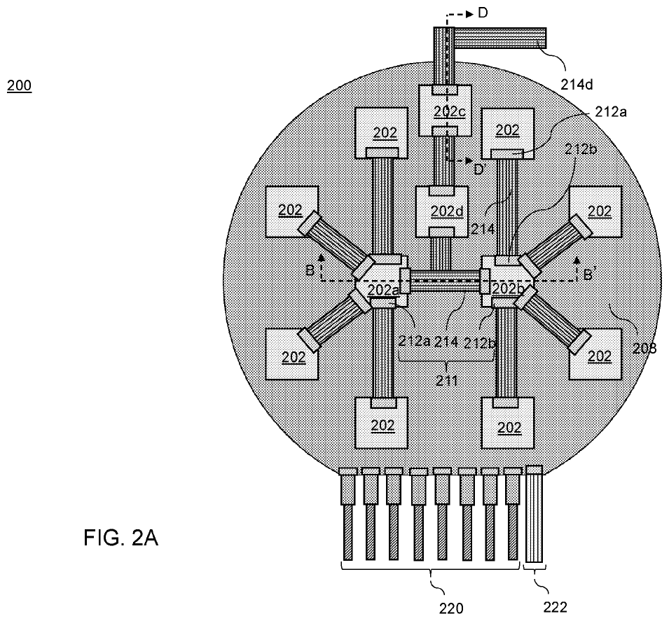

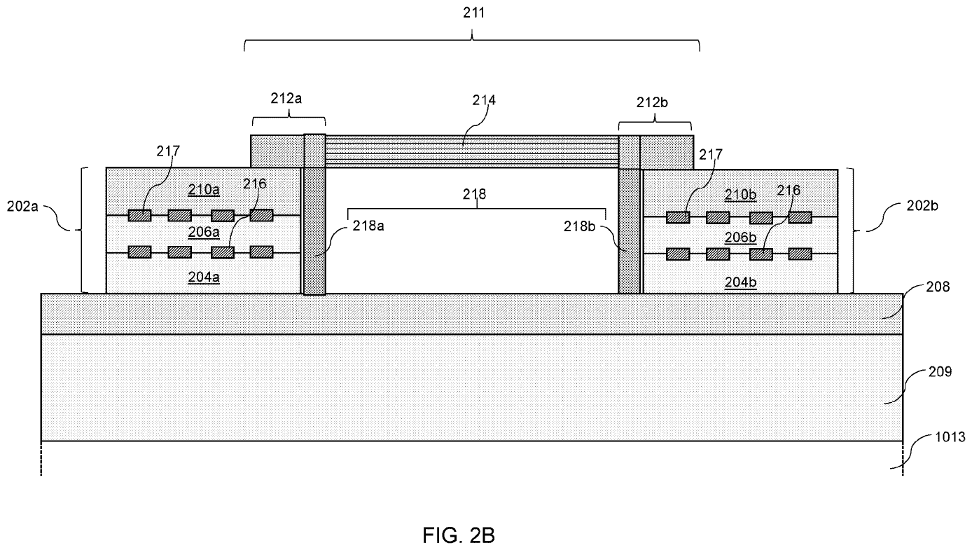

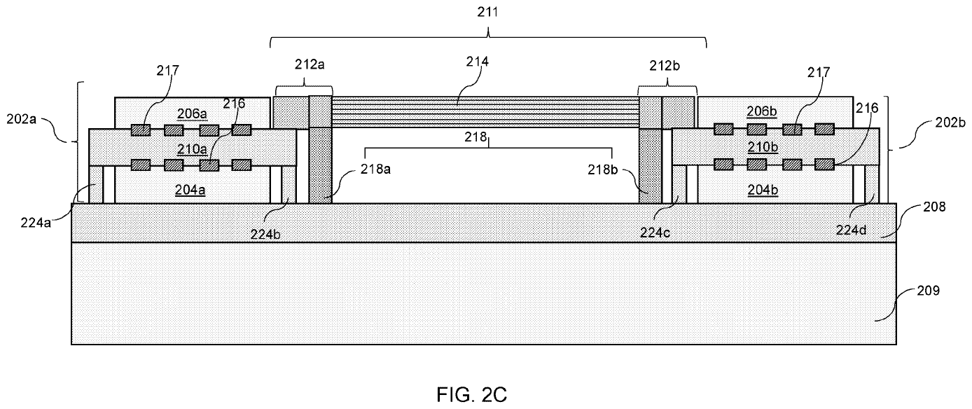

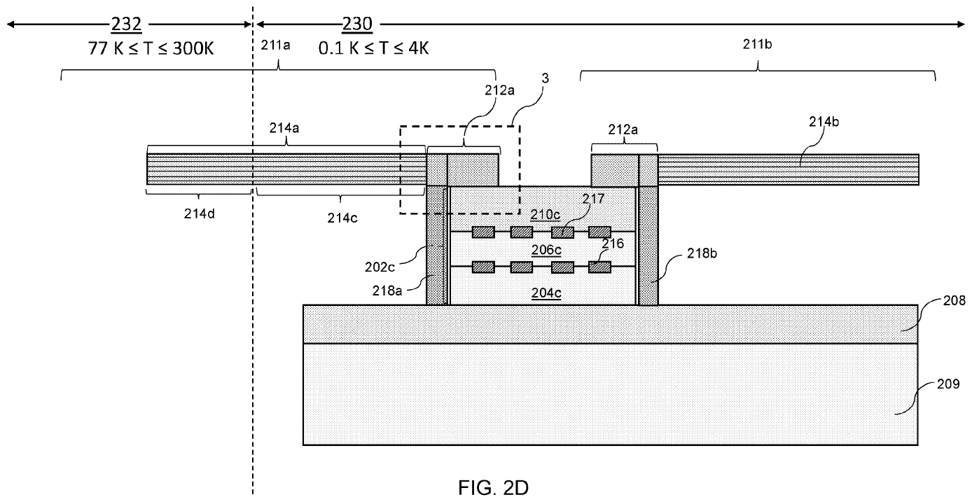

FIG. 2A is a top view of a hybrid electronic/photonic device 200 that may form a component of a hybrid computing system 1001, and FIG. 2B is a vertical cross-sectional view of a first portion of the hybrid electronic/photonic device 200, according to some embodiments. The plane defining the cross-sectional view of FIG. 2B is indicated by the cross-section B-B′ in FIG. 2A. The hybrid electronic/photonic device 200 may include a plurality of die stacks 202, as shown in FIG. 2A. In some embodiments, each of the plurality of die stacks 202 may be structurally similar to one another and may be configured to perform similar electronic and photonic operations. In other embodiments, various different types of die stacks (not shown) may be provided that may be configured to perform respective different electronic and photonic operations.

As shown in FIG. 2B, the first portion of the hybrid electronic/photonic device 200 may include a first die stack 202a and a second die stack 202b. The first die stack 202a and the second die stack 202b may respectively include a first photonic die 204a and a second photonic die 204b. Each of the first photonic die 204a and the second photonic die 204b may be respectively electrically connected to a first electronic die 206a and a second electronic die 206b. In the embodiment shown in FIG. 2B, each of the first photonic die 204a and the second photonic die 204b are directly bonded to the first electronic die 206a and the second electronic die 206b, respectively. Thus, each of the first photonic die 204a and the second photonic die 204b are in direct mechanical contact and in electrical communication to the first electronic die 206a and the second electronic die 206b, respectively.

Each of the first photonic die 204a and the second photonic die 204b may also be optically coupled to one another through a photonic interposer 208. The photonic interposer 208 may be configured to allow optical signals to propagate between the first photonic die 204a and the second photonic die 204b. For example, the photonic interposer 208 may include various photonic transmission pathways, such as optical waveguides. In one embodiment, the photonic interposer includes a semiconductor substrate, such as a silicon wafer, containing optical waveguides, such as silicon or silicon nitride waveguides. Other materials may also be used for the photonic interposer. The photonic interposer 208 may be directly or indirectly mechanically coupled to a cryogenic device 1013 that may maintain the photonic interposer at cryogenic temperatures (e.g., temperatures between 0.1 K and 4K).

In one embodiment, the photonic interposer 208 may be indirectly mechanically coupled to a cryogenic device 1013 (e.g., a cryostat) through an optional heat spreader 209.

Heat generated by the first die stack 202a and the second die stack 202b may be removed by the heat spreader 209. The heat spreader 209 may include a material having a high thermal conductivity that may increase a rate of heat flow from the first die stack 202a and the second die stack 202b through the photonic interposer 208 to the cryogenic device (e.g., such as a liquid helium chamber of the cryogenic device 1013). For example, the heat spreader 209 may include a copper plate or silicon wafer that is mounted between the photonic interposer 208 and the cryogenic device 1013. The heat spreader 209 may be maintained at a temperature of 4K or below during operation of the system 1001. Alternatively, the heat spreader 209 may be omitted and the photonic interposer 208 may be directly mechanically coupled to a cryogenic device 1013.

Photonic components (not shown) within each of the first photonic die 204a and the second photonic die 204b may include various electro-optic devices, such as the electro-optic switch 100 described above with reference to FIG. 1A. In this regard, each of the first electronic die 206a and the second electronic die 206b may be electrically coupled to the respective first photonic die 204a and the second photonic die 204b and may provide electrical signals that may be used control photonic operations performed by the first photonic die 204a and the second photonic die 204b.

Each of the components of the first die stack 202a and the second die stack 202b may be fabricated using solid state (e.g., semiconductor) device fabrication processes and materials. Similarly, bonding practices used in the semiconductor device industry may be used to bond the various components of the first die stack 202a and the second die stack 202b. For example, the first photonic die 204a may be bonded to the first electronic die 206a using bonding structures 216, such as bonding pads, bump bonds, or solder balls. The second photonic die 204b may similarly be bonded to the second electronic die 206b using the bonding structures 216.

Each of the first die stack 202a and the second die stack 202b may further include a first electrical interposer 210a and a second electrical interposer 210b electrically coupled to the first electronic die 206a and the second electronic die 206b, respectively. In the embodiment shown in FIG. 2B, the first electrical interposer 210a and the second electrical interposer 210b are also mechanically coupled to and are located on the first electronic die 206a and the second electronic die 206b, respectively. For example, the first electrical interposer 210a and the second electrical interposer 210b may be bonded to the first electronic die 206a and the second electronic die 206b, respectively, by one or more bonding structures 217, such as bonding pads, bump bonds, or solder balls. In one embodiment, the first electrical interposer 210a and the second electrical interposer 210b may be in physical contact with the first electronic die 206a and the second electronic die 206b, respectively. In another embodiment, the first electrical interposer 210a and the second electrical interposer 210b may be vertically spaced from the first electronic die 206a and the second electronic die 206b, respectively, by the bonding structures 217.

The hybrid electronic/photonic device 200 shown in FIG. 2B may further include an electrical coupler 211 coupled to and electrically connecting the first electrical interposer 210a and the second electrical interposer 210b. Electrical signals may flow between the first electronic die 206a and the second electronic die 206b through the respective the first electrical interposer 210a and the second electrical interposer 210b and the electrical coupler 211.

The electrical coupler 211 may include a first connector 212a and a second connector 212b that are electrically coupled to one another by a cable 214, such as a flexible cable.

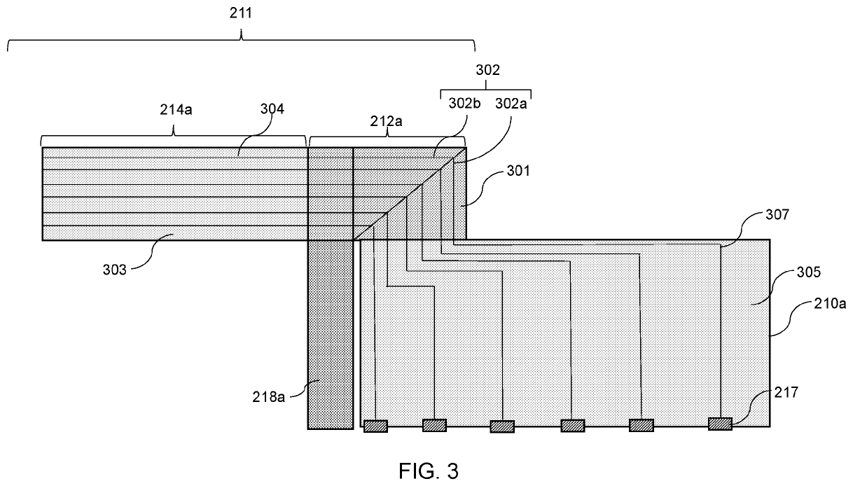

Each of the first connector 212a and a second connector 212b may include electrically conducting elements that may be electrically coupled to the first electrical interposer 210a and the second electrical interposer 210b, respectively, as described in greater detail with reference to FIG. 3, below. The first connector 212a and the second connector 212b may be configured to have a thermal expansion coefficient that differs by 10% or less, such as by 0 to 8%, for example by 1 to 5%, from a thermal expansion coefficient of the first electrical interposer 210a and the second electrical interposer 210b, respectively. In this regard, the first connector 212a, the second connector 212b, the first electrical interposer 210a, and the second electrical interposer 210b may include similar materials, for example, silicon, glass, a ceramic, a polymer material, etc., which contain electrically conductive wires or traces, as described in more detail below with reference to FIG. 3.

The electrical coupler 211 may further include a rigid support structure 218 configured to support the first connector 212a and the second connector 212b at a pre-determined distance above a top surface of the photonic interposer 208. For example, the support structure may include a first support portion 218a and a second support portion 218b. As shown in FIG. 2B, for example, the first support portion 218a may be mechanically connected to the first connector 212a and the second support portion 218b may be mechanically connected to the second connector 212b. The first support portion 218a and the second support portion 218b may have any suitable shape, such as a vertical pillar or vertical wall shape. The bottoms of the first support portion 218a and the second support portion 218b may be configured to rest on a top surface of the photonic interposer 208.

As shown in FIG. 2A, the various die stacks (e.g., first die stack 202a, second die stack 202b) in the hybrid electronic/photonic device 200 may be electrically coupled to one another using similar electrical couplers 211. The various components of the hybrid electronic/photonic device 200 may be maintained at cryogenic temperatures such that quantum computing operations may be performed by the hybrid electronic/photonic device 200. Electrical and optical connections may also be formed between the hybrid electronic/photonic device 200, which may be kept at cryogenic temperatures (e.g., 0.1K to 4K), and other system components that may be held at higher temperatures (e.g., 77K to 300 K). For example, a second portion 214d of a cable (e.g., shown at the top of FIG. 2A) may electrically connect the hybrid electronic/photonic device 200 to other system components, as described with reference to FIG. 2D, below.

As further shown in FIG. 2A, the hybrid electronic/photonic device 200 may further include plurality of photonic couplers 220 that may be optically coupled to the pulsed pump laser 1011 (e.g., see FIG. 1B) to thereby provide laser pump radiation to the hybrid electronic/photonic device 200. One or more additional optical couplers 222 may optically couple photonic signals between the hybrid electronic/photonic device 200 and other components of the hybrid computing system 1001. The photonic signals carried by the one or more additional optical couplers 222 may encode data to be processed by the hybrid electronic/photonic device 200. In this regard, the hybrid electronic/photonic device 200 may be configured to perform one or more quantum computing operations on photonic data provided by the one or more additional optical couplers 222. The one or more additional optical couplers 222 may also provide the results of quantum computing operations performed by the hybrid electronic/photonic device 200 to other sub-systems for further processing or readout.

FIG. 2C is a vertical cross-sectional view of the first portion of the hybrid electronic/photonic device in which the first die stack 202a and the second die stack 202b each have an alternative configuration, according to an alternative embodiment. The plane defining the cross-sectional view of FIG. 2C is indicated by the cross-section B-B′ in FIG. 2A. In this alternative embodiment, each of the first die stack 202a and the second die stack 202b may include a respective first photonic die 204a and a second photonic die 204b. Each of the first die stack 202a and the second die stack 202b may also include a respective first electronic die 206a and a second electronic die 206b. In contrast to the embodiment of FIG. 2B, however, the first photonic die 204a is not directly connected to the first electronic die 206a and the second photonic die 204b is not directly connected to the second electronic die 206b. Rather, a first electrical interposer 210a may be disposed between the first photonic die 204a and the first electronic die 206a and a second electrical interposer 210b may be disposed between the second photonic die 204b and the second electronic die 206b, as shown in FIG. 2C.

In this alternative embodiment, the first electronic die 206a may be laterally offset from an edge of the top surface of the first electrical interposer 210a. The bottom of the first electrical connector 212a is electrically coupled to the portion of the top surface of the first electrical interposer 210a that is exposed on the side of the laterally offset first electronic die 206a. Furthermore, the second electronic die 206b may be laterally offset from an edge of the top surface of the second electrical interposer 210b. The bottom of the second connector 212b is electrically coupled to the portion of the top surface of the second electrical interposer 210b that exposed on the side of the laterally offset second electronic die 206b.

The alternative embodiment of FIG. 2C may further include a photonic interposer 208 that may be optically coupled to the first photonic die 204a and the second photonic die 204b, as described above with regard to the embodiment of FIG. 2B. Similarly, the first electrical interposer 210a and the second electrical interposer 210b may be electrically coupled to one another with an electrical coupler 211 that includes a first connector 212a, a second connector 212b, and a cable 214 that electrically couples the first connector 212a to the second connector 212b. As shown in FIG. 2C, the first connector 212a may be electrically coupled to the first electrical interposer 210a and the second connector 212b may be electrically coupled to the second electrical interposer 210b. The electrical coupler 211 may further include a rigid support structure 218 having a first support portion 218a and a second support portion 218b mechanically coupled to the first connector 212a and the second connector 212b, respectively. The first support portion 218a and the second support portion 218b may each be configured to support the electrical coupler 211 at a predetermined distance above the photonic interposer 208.

In the alternative embodiment of FIG. 2C, additional support portions (224a, 224b, 224c, 224d) may also be provided. The additional support portions may provide further mechanical support to first electrical interposer 210a and the second electrical interposer 210b, as shown in FIG. 2C. Specifically, the additional support portions may include the same material as the first and second electrical interposers but may lack electrical wires or traces therein. The first and second photonic dies (204a, 204b) may be laterally offset from edges of the bottom surface of the respective first and second electrical interposers 210a. The top surfaces of the additional support portions (224a, 224b, 224c, 224c) may contact the portions of the bottom surfaces of the respective first and second electrical interposers (210a, 210b) that are exposed on the sides of the laterally offset first and second photonic die 204a, 204b. The bottom surfaces of the additional support portions (224a, 224b, 224c, 224c) may rest on the top surface of the photonic interposer 208.

FIG. 2D is a vertical cross-sectional view of a second portion of the hybrid electronic/photonic device 200, according to some embodiments. The plane defining the cross-sectional view of FIG. 2D is indicated by the cross-section D-D′ in FIG. 2A. The second portion of the hybrid electronic/photonic device 200, shown in FIG. 2D, may include a third die stack 202c including a third photonic die 204c, a third electronic die 206c, and a third electrical interposer 210c electrically connected to the third electronic die 206c. The third electrical interposer 210c may be located above the third electronic die 206c, as shown in FIG. 2D, or between the third electronic die 206c and the third photonic die 204c, as shown in FIG. 2C.

The third die stack 202c may be electrically connected to a first electrical coupler 211a having a first cable 214a. The third die stack 202c may be further electrically connected to a second electrical coupler 211b having a second cable 214b. The first cable 214a may be electrically connected to a first connector 212a and the second cable 214b may be electrically connected to a second connector 212b. Further, as in the other embodiments described above, the first connector 212a and the second connector 212b may have a coefficient of thermal expansion that differs by 10% or less from the third electrical interposer 210c of the third die stack 202c. The second cable 214b may connect the third die stack 202c to other components within the hybrid electronic/photonic device 200. For example, the second cable 214b may connect the third die stack 202c to a fourth die stack 202d, as shown in FIG. 2A.

The third die stack 202c may be located near a peripheral region of the hybrid electronic/photonic device 200, as shown in FIG. 2A. As such, the first cable 214a may be configured to extend from a first region 230 to a second region 232. The first region 230 may be a cryogenic region that may be held at cryogenic temperatures, while the second region 232 may be a region that is held at higher temperatures. For example, the first region 230 may be held at liquid helium temperatures (e.g., 0.1K≤T≤4K) while the second region 232 may be held at liquid nitrogen temperatures and above (e.g., 77K≤T≤300K). As such, the first cable 214a may have a first portion 214c extending within region the first region 230 and a second portion 214d extending within the second region 232.

FIG. 3 is an enlarged view of area 3 of the hybrid electronic/photonic device 200 of FIG. 2D, according to some embodiments. The view of FIG. 3 includes the first connector 212a, a portion of the first electrical interposer 210a, a portion of the first support portion 218a, and a portion of the first cable 214a. The first connector 212a may include a plurality of electrically conducting elements 302. Each electrically conducting element 302 may include a conductive wire or trace which includes a vertical portion 302a and a horizontal portion 302b. The horizontal portion 302b of the electrically conducting elements 302 may extend from the first connector 212a into the first cable 214a. The first cable 214a may include a plurality of additional electrically conductive elements (e.g., wires or traces) 304.

Each of the plurality of additional electrically conductive elements 304 may be electrically connected to a respective horizontal portion 302b of the plurality of electrically conducting elements 302 within the first connector 212a. The plurality of additional electrically conductive elements 304 of the first cable 214a may include various materials and may be configured in various ways in other embodiments.

In some embodiments, the first cable 214a may include a different material from that of the first connector 212a. In other embodiments, the first cable 214a and the first connector 212a may include similar materials or the same materials. For example, the first connector 212a may include the electrically conducting elements 302 embedded within a matrix 301 (e.g., a semiconductor or an insulating matrix). The matrix 301 may include one or more of a semiconductor material (e.g., undoped silicon), a glass, a ceramic, or a polymer material.

The first cable 214a may include a flexible polymer material (e.g., polyimide) matrix 303 embedding the additional electrically conductive elements 304. For example, the first connector 212a may include the matrix 301 (e.g., silicon or glass matrix) that is mechanically rigid, while the first cable 214a may include a flexible polymer material matrix 303 that allows the first cable 214a to be mechanically flexible.

The electrical interposer 210a may include a plurality of electrically conducting elements 307, such as wires or traces, embedded in a semiconductor or insulating matrix 305. The electrically conducting elements 307 electrically connect the vertical portions 302a of the electrically conducting elements 302 to the bonding structures 217 of the respective third electronic die 206c shown in FIG. 2D. Specifically, the electrical interposer 210a spreads out the electrical signals between the dense electrically conducting elements 302 and the spaced apart bonding structures 217.

The first connector 212a may have a thermal expansion coefficient that differs by 10% or less, such as by 0 to 8%, for example by 1 to 5%, from a thermal expansion coefficient of the first electrical interposer 210a. In this regard, the matrix 301 of first connector 212a and the matrix 305 of first electrical interposer 210a may include the same material, for example, a semiconductor (e.g., silicon), a glass, a ceramic, a polymer material, etc., which contain the respective electrically conducting elements 302 and 307 (e.g., wires, traces). For example, both the first connector 212a and the first electrical interposer 210a may include the same matrix (e.g., silicon), which have the same coefficient of thermal expansion. Likewise, the second connector 212b and the second electrical interposer 210b may include the same matrix (e.g., silicon), which have the same coefficient of thermal expansion. Furthermore, in one embodiment, the first support portion 218a may include the same material as the matrix of the first connector 212a and the first electrical interposer 210a. Likewise, the second support portion 218b may include the same material as the matrix of the second connector 212b and the second electrical interposer 210b.

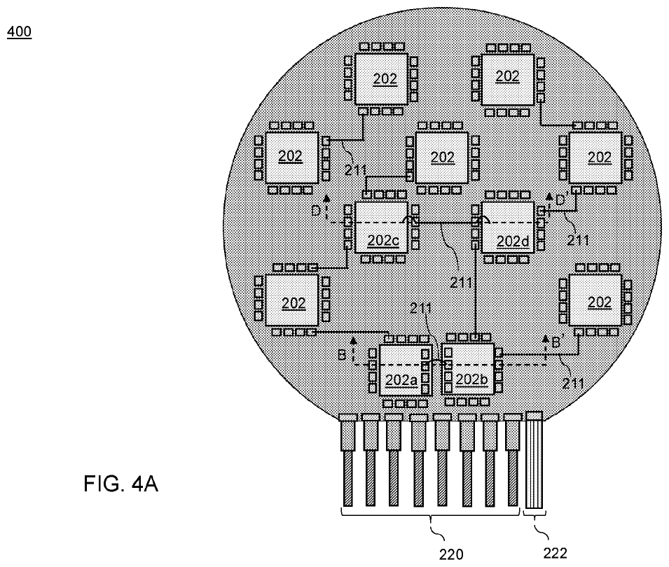

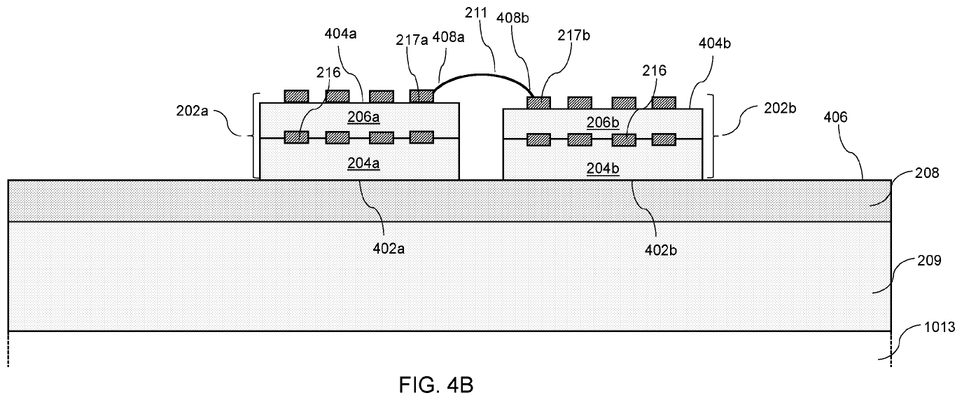

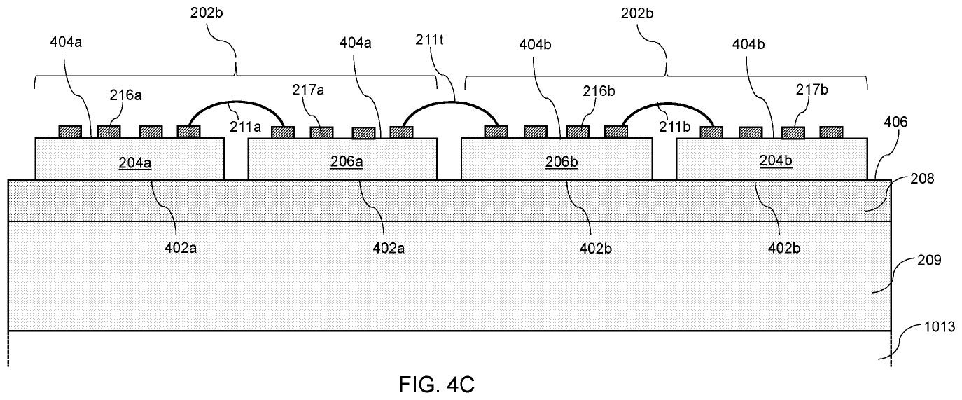

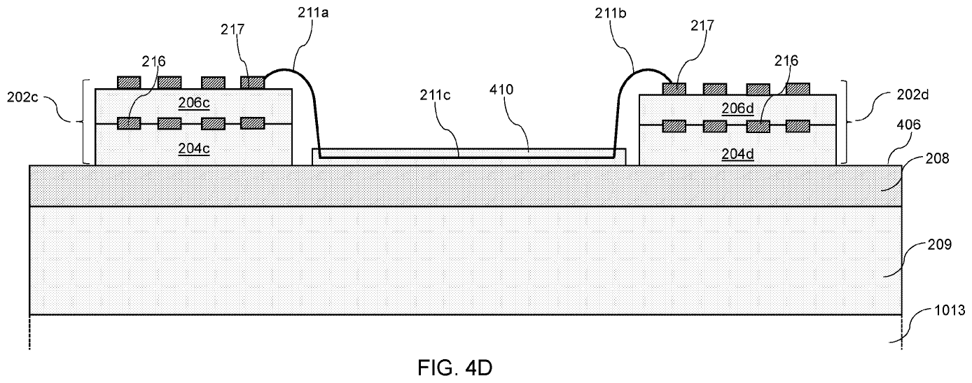

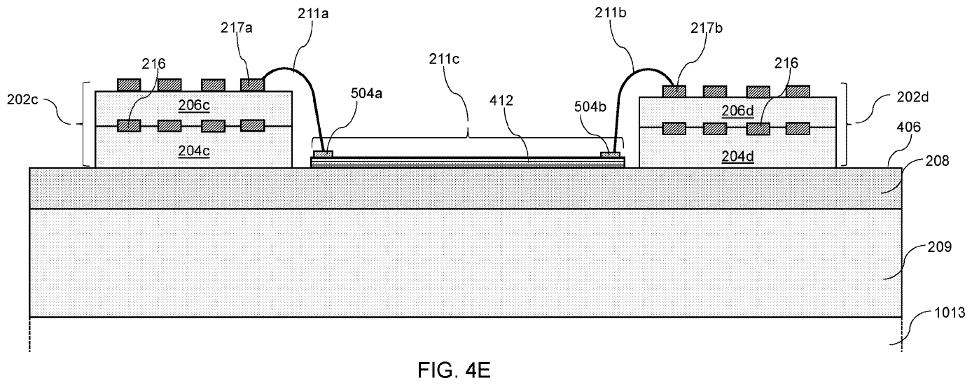

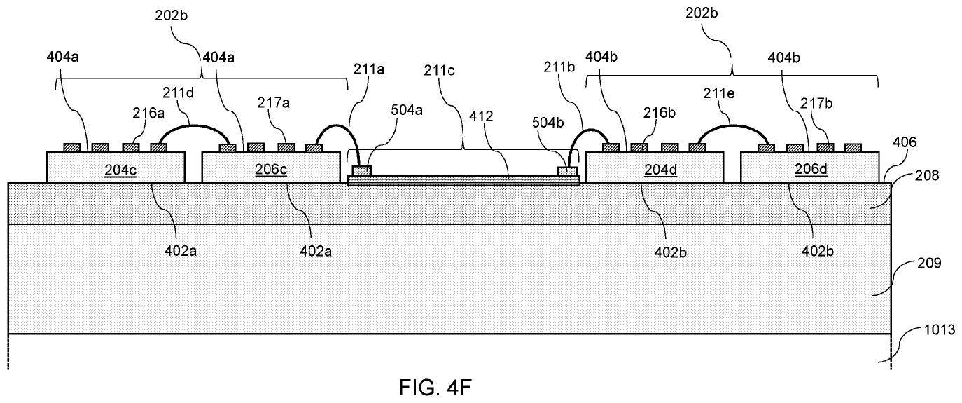

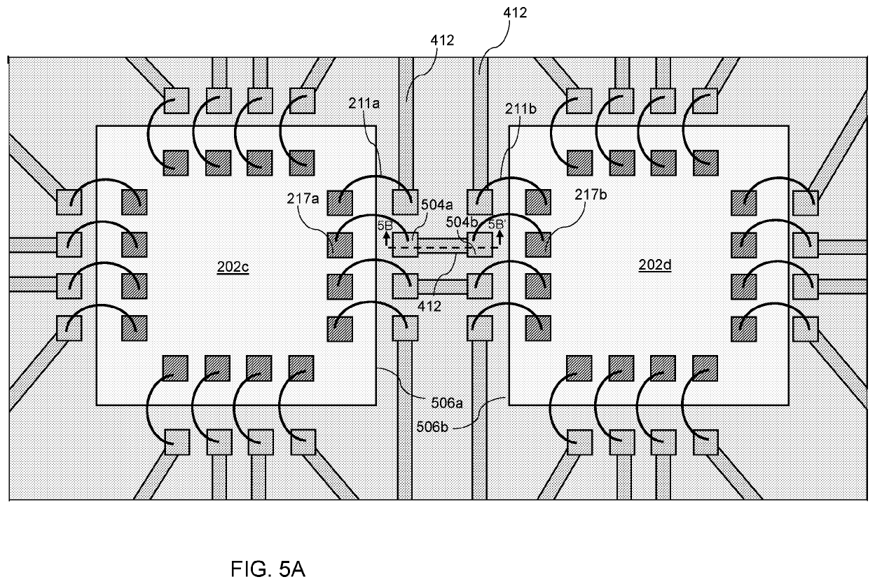

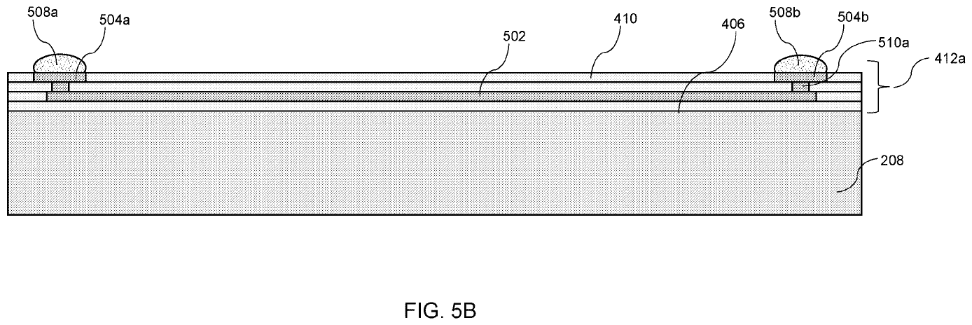

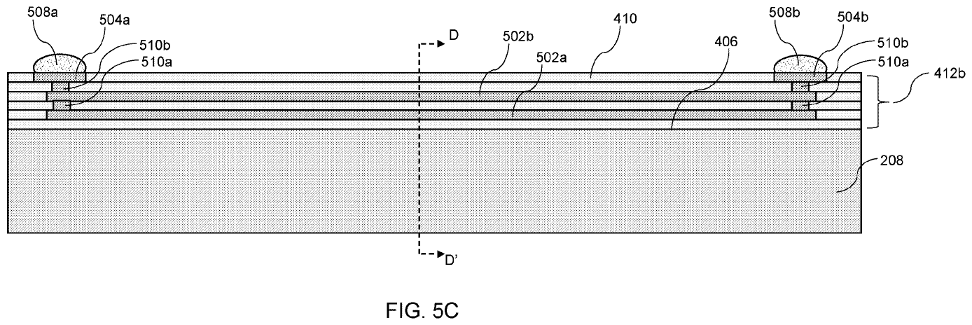

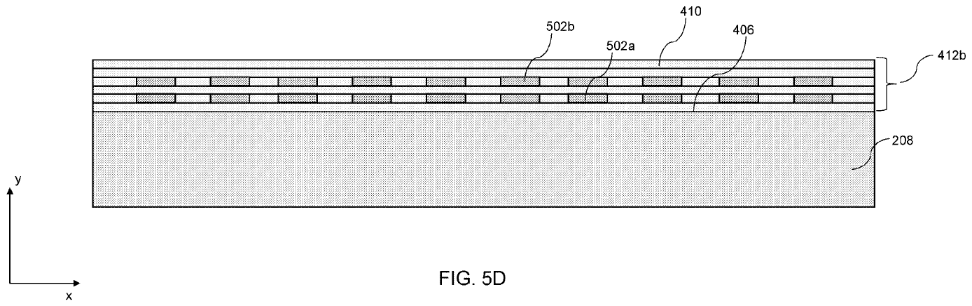

FIG. 4A is a top view of a further hybrid electronic/photonic device 400 that may form a sub-system of a hybrid computing system 1001, according to additional embodiments. The hybrid electronic/photonic device 400 may include various alternative configurations for the electrical couplers 211, as described in greater detail with reference to FIGS. 4B to 5D, below. The electrical couplers 211 may comprise conductive wires in these additional embodiments.

FIG. 4B is a vertical cross-sectional view of a first portion of the hybrid electronic/photonic device 400. The cross-sectional view of FIG. 4B is defined by the cross section B-B′ in FIG. 4A. The hybrid electronic/photonic device 400 includes a first electronic/photonic integrated circuit (204a, 206a) and a second electronic/photonic integrated circuit (204b, 206b) mounded on the same substrate. In one embodiment, the substrate may be a high density packaging substrate (e.g., high density build up (HDBU) polymer substrate). In another embodiment, the substrate may be the above described photonic interposer 208, such as a silicon interposer. In this embodiment, the first electronic/photonic integrated circuit (204a, 206a) is mounted on and optically coupled to the photonic interposer 208, and the second electronic/photonic integrated circuit (204b, 206b) is mounted on and optically coupled to the photonic interposer 208. As with other embodiments described above, the photonic interposer 208 may be directly or indirectly coupled to a cryogenic device 1013 (e.g., a cryostat) through an optional heat spreader 209. Also, as with other embodiments, the first electronic/photonic integrated circuit (204a, 206a), the second electronic/photonic integrated circuit (204b, 206b), and the photonic interposer 208 may optionally have respective coefficients of thermal expansion that differ by 10% or less.

The first electronic/photonic integrated circuit (204a, 206a) may include a first photonic die 204a and a first electronic die 206a, assembled as a first die stack 202a. The second electronic/photonic integrated circuit (204b, 206b) may include a second photonic die 204b and a second electronic die 206b, assembled as a second die stack 202b. In contrast to other embodiments described above, in the additional embodiments, the first electronic/photonic integrated circuit (204a, 206a) and the second electronic/photonic integrated circuit (204b, 206b) may respectively exclude the first electrical interposer 210a and the second electrical interposer 210b described above with reference to FIGS. 2B and 2C. Rather, in the additional embodiments of the hybrid electronic/photonic device 400, the electrical connections between the first electronic/photonic integrated circuit (204a, 206a) and the second electronic/photonic integrated circuit (204b, 206b) may be formed directly between first bonding structures 217a of the first electronic/photonic integrated circuit (204a, 206a) and second bonding structures 217b of the second electronic/photonic integrated circuit (204b, 206b).

In this regard, as shown in FIG. 4B, the first electronic/photonic integrated circuit (204a, 206a) may include a first proximal side 402a that is mounted to a surface 406 of the photonic interposer 208 and a first distal side 404a that includes one or more a first electrical connectors (e.g., first bonding structures 217a). Similarly, the second electronic/photonic integrated circuit (204b, 206b) may include a second proximal side 402b that is mounted to the surface 406 of the photonic interposer 208 and a second distal side 404b that includes one or more a second electrical connectors (e.g., second bonding structures 217b).

A first end 408a of the electrical coupler 211 may be electrically coupled to the first electrical connector 217a and a second end 408b of the electrical coupler 211 may be electrically coupled to the second electrical connector 217b such that the first electronic/photonic integrated circuit (204a, 206a) and the second electronic/photonic integrated circuit (204b, 206b) are electrically coupled to one another. In this embodiment, the electrical coupler 211 may be conductive wire. The first end 408a may be wire-bonded to the first electrical connector 217a and the second end 408b may be wire bonded to the second electrical connector 217b. As shown in FIG. 4B, the conductive wire may be suspended between the first electronic/photonic integrated circuit (204a, 206a) and the second electronic/photonic integrated circuit (204b, 206b) such that the conductive wire does not make contact with the surface 406 of the photonic interposer 208.

In an alternative embodiment, two or more photonic and/or electronic dies may be located side by side rather than in a stack, and are electrically connected using similar conductive wire electrical couplers 211, as described in greater detail with reference to FIG. 4C below. FIG. 4C is a vertical cross-sectional view of the first portion of the hybrid electronic/photonic device 400 in which the electronic and photonic dies have an alternative configuration, according to an alternative embodiment. In the alternative embodiment of FIG. 4C, each of the first photonic die 204a and the first electronic die 206a may have a first proximal side 402a that is mounted to the surface 406 of the substrate, such as the photonic interposer 208, and a first distal side 404a that includes electrical connectors (216a, 217a). Similarly, each of the second photonic die 204b and the second electronic die 206b may have a second proximal side 402b that is mounted to the surface 406 of the substrate, such as the photonic interposer 208, and a second distal side 404b that includes electrical connectors (216b, 217b). As shown in FIG. 4C, the first photonic die 204a and the first electronic die 206a may be located adjacent to one another (i.e., side by side) on the same surface 406 of the substrate, and the second photonic die 204b and the second electronic die 206b may also be located adjacent to one another on the same surface 406 of the substrate. Similarly, the first electronic die 206a and the second electronic die 206b may likewise be located adjacent to one another on the same surface 406 of the substrate, as shown in FIG. 4C.

A first electrical coupler 211a may electrically couple the first electronic die 204a to the first photonic die 206a and a second electrical coupler 211b may electrically couple the second photonic die 204b to the second electronic die 206b. Further, as shown in FIG. 4C, a third electrical coupler 211t may electrically couple the first electronic die 206a to the second electronic die 206b. Each of the first electrical coupler 211a, the second electrical coupler 211b, and the third electrical coupler 211t may comprise a conductive wire that is suspended between respective dies such that the conductive wire does not make contact with the surface 406 of the substrate, such as the photonic interposer 208. As with the embodiment described above with reference to FIG. 4B, each of the electrical couplers (211a, 211b, 211t) may be wire bonded to respective electrical connectors (216a, 217a, 216b, 217b).

Thus, in the embodiments of FIGS. 4B and 4C, when the dies are located close to each other on the surface 406 of the substrate, then they may be bonded to each other by a suspended conductive wire electrical coupler 211, which is not supported by the surface 406 of the substrate. However, as described in greater detail with reference to FIGS. 4D to 5D, below, when the dies are located relatively far from each other on the surface 406 of the substrate, then they may be bonded to each other by a conductive wire electrical coupler 211 that has at least a portion that is supported directly or indirectly by the surface 406 of the substrate, such as the photonic interposer 208.

FIG. 4D is a vertical cross-sectional view of a second portion of the hybrid electronic/photonic device 400 in which the electrical coupler (211a, 211b, 211c) has a portion 211c that extends along the surface 406 of a substrate, such as a photonic interposer 208. The cross-sectional view of FIG. 4D is indicated by the cross section D-D′ in FIG. 4A. As shown in FIG. 4D, the second portion of the electronic/photonic device 400 may include a third electronic/photonic integrated circuit (204c, 206c) and a fourth electronic/photonic integrated circuit (204d, 206d). Each of the third electronic/photonic integrated circuit (204c, 206c) and the fourth electronic/photonic integrated circuit (204d, 206d) may be configured as described above with reference to FIG. 4B. In contrast to the first portion of the device 400 shown in FIG. 4B, in the second portion of the device 400 shown in FIG. 4D, the third electronic/photonic integrated circuit (204c, 206c) and the fourth electronic/photonic integrated circuit (204d, 206d) may be separated by a larger distance than the distance between the first electronic/photonic integrated circuit (204a, 206a) and the second electronic/photonic integrated circuit (204b, 206b) of FIG. 4B. Thus, a portion 211c of the electrical coupler (211a, 211b, 211c) is located on the surface 406 of a photonic interposer 208. In this regard, the electrical coupler (211a, 211b, 211c) is a continuous conductive wire which includes a first end 211a that is electrically connected to the third electronic die 206c, a second end 211b that is electrically connected to the fourth electronic die 206d and a middle portion 211c located on the surface 406 of the substrate. The first end 211a and the second end 211b are electrically connected to the middle portion 211c that is formed along the surface 406 of the photonic interposer 208. In some embodiments, the middle portion 211c that is formed along the surface 406 may further be embedded in a dielectric material 410 (e.g., electrical insulation material) that is formed on the surface 406 of the substrate, such as a photonic interposer 208. The dielectric material may comprise a polymer material, silicon nitride, silicon oxide and/or alumina. Thus, if the dielectric material 410 is present, then the middle portion 211c is separated from the surface 406 of the substrate by the dielectric material 410. In this case, the middle portion 211c is indirectly supported by the surface 406 of the substrate. If the dielectric material 410 is omitted between the middle portion 211c and the surface 406 of the substrate, then the middle portion 211c is directly supported by the surface 406 of the substrate and directly contacts the surface 406 of the substrate.

The electrical coupler 211 which contains a portion which is directly or indirectly supported by the surface 406 of the substrate is advantageous because it eliminates or reduces wire sag and potential short circuits. It also improves the reliability of the electrical interconnections and parasitic capacitance.

In other embodiments, the electrical coupler (211a, 211b, 211c) may include separate conducting elements, at least some of which may be embedded in the dielectric material 410, as described in greater detail with reference to FIG. 4E, below. FIG. 4E is a vertical cross-sectional view of the second portion of the hybrid electronic/photonic device 400 in a further configuration in which the electrical coupler (211a, 211b, 211c) includes one or more redistribution layers 412, according to the alternative embodiments. Each of the one or more redistribution layers 412 may include one or more electrically conductive elements 502 embedded in the dielectric material 410 matrix, as described in greater detail with reference to FIGS. 5B to 5D. As shown in FIG. 4E, a first wire-bond finger 504a is electrically coupled to a first end of the one or more redistribution layers 412, and a second wire-bond finger 504b is electrically coupled to a second end of the one or more redistribution layers 412. The electrical coupler (211a, 211b, 211c) may further include a first conductive wire 211a having a first end that is wire-bonded to a first electrical connector 217a of the third electronic die 206c and a second end that is wire bonded to the first wire-bond finger 504a, as shown in FIG. 4E. Similarly, the electrical coupler (211a, 211b, 211c) may include a second conductive wire 211b having a third end that is wire-bonded to a second electrical connector 217b of the fourth electronic die 206d and a fourth end that is wire bonded to the second wire-bond finger 504b.

FIG. 4F is a vertical cross-sectional view of the second portion of the hybrid electronic/photonic device 400 in which the electrical coupler (211a, 211b, 211c, 211d, 211e) includes one or more redistribution layers 412 and electrically conductive wires which electrically connect electronic and photonic die which are located side by side on the surface 406 of the substrate rather than in stacks, according to an alternative embodiment. As shown, third electronic/photonic integrated circuit (204c, 206c) and the fourth electronic/photonic integrated circuit (204d, 206d) may be configured such that each of the photonic dies (204c, 204d) and electronic dies (206c, 206c) include a proximal side (402a, 402b) mounted to the surface 406 of the photonic interposer 208. Further, as in the alternative embodiment of FIG. 4C, each of the photonic dies (204c, 204d) and electronic dies (206c, 206c) include a distal side (404a, 404b) having electrical connectors (216a, 217a, 216b, 217b). As shown, first and second electrical couplers (211a, 211b) may electrically couple first and second wire-bond fingers (504a, 504b) of the one or more redistribution layers 412 (which comprise the electrical coupler 211c) to the third electronic die 206c and the fourth electronic die 206d, respectively. Similarly, a fourth electrical coupler 211d may electrically couple the third photonic die 204c to the third electronic die 206c, and a fifth electrical coupler 211e may electrically couple the fourth photonic die 204d to the fourth electrical die 206d.

FIG. 5A is a top view of an enlarged portion of the hybrid electronic/photonic device 400 of FIG. 4A, according to some embodiments. As shown in FIG. 5A, a third die stack 202c and a fourth die stack 202d may be electrically coupled to an electrical coupler (211a, 211b, 412, 504a, 504b) that includes a redistribution layer 412 and a plurality of electrically conducting wires (211a, 211b). As shown, a first plurality of wire-bond fingers 504a may be formed proximate to a first edge 506a of the third electronic/photonic integrated circuit (i.e., third die stack 202c) and a second plurality of wire-bond fingers 504b may be formed proximate to a second edge 506b of the fourth electronic/photonic integrated circuit (i.e., fourth die stack 202d). The first plurality of wire-bond fingers 504a may be electrically connected to a first end of a respective conductive element 502 of the one or more redistribution layers 412. Similarly, the second plurality of wire-bond fingers 504b may be electrically connected to a second end of a respective conductive element 502 (shown in FIG. 5B) of the conductive one or more redistribution layers 412. A first plurality of conductive wires 211a may electrically connect the first plurality of wire-bond fingers 504a to a first plurality of electrical connectors 217a on the third electronic/photonic integrated circuit 202a, and a second plurality of conductive wires 211b may electrically connect the second plurality of wire-bond fingers 504b to a second plurality of electrical connectors 217b on the fourth electronic/photonic integrated circuit 202b.

FIG. 5B is a vertical cross-sectional view of a portion of a first redistribution layer 412a having a single conductive element 502, and FIG. 5C is a vertical cross-sectional view of a portion of a second redistribution layer 412b having two conductive elements (502a, 502b), according to the additional embodiments. The cross-sectional views of FIGS. 5B and 5C correspond to the cross-section B-B′ in FIG. 5A. In each of the first redistribution layer 412a and the second redistribution layer 412b, the respective conductive elements 502 or (502a, 502b) may be embedded in a multi-layer dielectric matrix 410. The first redistribution layer 412a and the second redistribution layer 412b may each be formed on the surface 406 of the substrate, such as the photonic interposer 208, using semiconductor device manufacturing techniques. As shown in FIGS. 5B and 5C, each of the first and second wire-bond fingers (504a, 504b) may be provided with respective solder portions (508a, 508b) that may be used to form wire bonds with the respective conductive wires (211a, 211b), as shown in FIG. 5A.

As shown in FIG. 5C, the wire-bond fingers (504a, 504b) may be electrically connected to the first and second conductive elements (502a, 502b) with respective conductive vias (510a, 510b). In various additional embodiments, one or more redistributions layers 412 may include three or more conductive elements 502 (not shown).

FIG. 5D is a further vertical cross-sectional view of the redistribution layer 412b of FIG. 5C, according to one embodiment. The cross-sectional view of FIG. 5D corresponds to the cross-section D-D′ in FIG. 5C. As shown, the redistribution layer 412b may include a plurality of conductive elements (502a, 502b) displaced from another along a first direction x and along a second direction y, and extending along a third direction (i.e., into the plane of FIG. 5D). Each of the conductive elements (502a, 502b) may be embedded within the multi-layer dielectric material 410.

In addition to quantum computing and cryogenic electronics applications, the assemblies of various disclosed embodiments may be used in datacom/telecom systems, integrated optics systems, as well as artificial intelligence systems which rely on co-integration of photonics with advanced CMOS. In this regard, heat removal and thermal control over localized regions of the photonic die elements may provide additional design flexibility for co-integration of complex ASIC circuits that generate heat with the photonic integrated circuits that typically include temperature sensitive integrated components, such as detectors (e.g., superconducting detectors), lasers, modulators, single-photon sources, etc.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed.

Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

1. A hybrid electronic/photonic device, comprising:
a substrate;
a first electronic/photonic integrated circuit mounted on the substrate;
a second electronic/photonic integrated circuit mounted on the substrate; and
an electrical coupler electrically connecting the first electronic/photonic integrated circuit to the second electronic/photonic integrated circuit, wherein at least a portion of the electrical coupler is supported by the substrate.

2. The hybrid electronic/photonic device of claim 1, wherein:
the first electronic/photonic integrated circuit comprises a first proximal side that is mounted to a surface of the substrate and a first distal side that contains a first electrical connector;
the second electronic/photonic integrated circuit comprises a second proximal side that is mounted to the surface of the substrate and a second distal side that contains a second electrical connector; and
a first end of the electrical coupler is electrically coupled to the first electrical connector and a second end of the electrical coupler is electrically coupled to the second electrical connector, and a middle portion of the electrical coupler is supported by the surface of the substrate.

3. The hybrid electronic/photonic device of claim 2, wherein the electrical coupler comprises a conductive wire in which the first end is wire-bonded to the first electrical connector, the second end is wire bonded to the second electrical connector, and the middle portion of the conductive wire is supported by the surface of the substrate.

4. The hybrid electronic/photonic device of claim 3, wherein:
the middle portion of the conductive wire is embedded in a dielectric material that is located between the surface of the substrate and the conductive wire; and
the middle portion of the conductive wire is indirectly supported by the surface of the substrate.

5. The hybrid electronic/photonic device of claim 3, wherein:
the middle portion of the conductive wire directly contacts the surface of the substrate; and
the middle portion of the conductive wire is directly supported by the surface of the substrate.

6. The hybrid electronic/photonic device of claim 2, wherein:
the electrical coupler comprises one or more redistribution layers supported by the surface of the substrate in a region between the first electronic/photonic integrated circuit and the second electronic/photonic integrated circuit; and
the one or more redistribution layers comprise one or more electrically conductive elements.

7. The hybrid electronic/photonic device of claim 6, wherein:
the one or more redistribution layers comprise two or more electrically conductive elements embedded within a dielectric matrix; and
the dielectric matrix is located on the surface of the substrate.

8. The hybrid electronic/photonic device of claim 7, wherein the one or more redistribution layers are indirectly supported by the surface of the substrate.

9. The hybrid electronic/photonic device of claim 6, wherein the electrical coupler further comprises:
a first wire-bond finger electrically coupled to a first end of the one or more redistribution layers;
a second wire-bond finger electrically coupled to a second end of the one or more redistribution layers;
a first conductive wire comprising a first end that is wire-bonded to the first electrical connector and a second end that is wire bonded to the first wire-bond finger; and
a second conductive wire comprising a third end that is wire-bonded to the second electrical connector and a fourth end that is wire bonded to the second wire-bond finger.

10. The hybrid electronic/photonic device of claim 6, wherein the electrical coupler further comprises:
a first plurality of wire-bond fingers formed proximate to a first edge of the first electronic/photonic integrated circuit and electrically connected to a first end of the one or more redistribution layers;
a second plurality of wire-bond fingers formed proximate to a second edge of the second electronic/photonic integrated circuit and electrically connected to a second end of the one or more redistribution layers;
a first plurality of conductive wires electrically connecting the first plurality of wire-bond fingers to a first plurality of electrical connectors on the first electronic/photonic integrated circuit; and
a second plurality of conductive wires electrically connecting the second plurality of wire-bond fingers to a second plurality of electrical connectors on the second electronic/photonic integrated circuit.

10. (canceled)

11. The hybrid electronic/photonic device of claim 10, wherein:
the substrate comprises a photonic interposer;
the first electronic/photonic integrated circuit comprises a first die stack comprising a first photonic die located on and optically coupled to the surface of the photonic interposer, and a first electronic die located over the first photonic die; and
the second electronic/photonic integrated circuit comprises a second die stack comprising a second photonic die located on and optically coupled to the surface of the photonic interposer, and a second electronic die located over the second photonic die.

12. The hybrid electronic/photonic device of claim 10, wherein:
the substrate comprises a photonic interposer;
the first electronic/photonic integrated circuit comprises a first photonic die located on and optically coupled to the surface of the photonic interposer, and a first electronic die located on the surface of the photonic interposer side by side with the first photonic die; and
the second electronic/photonic integrated circuit comprises a second photonic die located on and optically coupled to the surface of the photonic interposer, and a second electronic die located on the surface of the photonic interposer side by side with the second photonic die.

13. The hybrid electronic/photonic device of claim 1, wherein the substrate comprises a packaging substrate.

14. The hybrid electronic/photonic device of claim 1, further comprising:
a third electronic/photonic integrated circuit mounted on the substrate;
a fourth electronic/photonic integrated circuit mounted on the substrate; and
a second electrical coupler electrically connecting the third electronic/photonic integrated circuit to the fourth electronic/photonic integrated circuit, wherein the second electrical coupler is not supported by the substrate.

15. The hybrid electronic/photonic device of claim 14, wherein the second electrical coupler comprises a wire which is suspended above the substrate and does not contact the substrate.

16. The hybrid electronic/photonic device of claim 14, wherein the first electronic/photonic integrated circuit and the second electronic/photonic integrated circuit are separated by a larger distance than a distance between the third electronic/photonic integrated circuit and the fourth electronic/photonic integrated circuit.

17. A method of forming an electronic/photonic device, comprising:
mounting a first electronic/photonic integrated circuit on a substrate;
mounting a second electronic/photonic integrated circuit the substrate; and
electrically connecting the first electronic/photonic integrated circuit to the second electronic/photonic integrated circuit using an electrical coupler, wherein at least a portion of the electrical coupler is supported by the substrate.

18. The method of claim 17, wherein the electrical coupler comprises a conductive wire in which a first end of the conductive wire is wire-bonded to the first electronic/photonic integrated circuit, a second end of the conductive wire is wire bonded to the second electronic/photonic integrated circuit, and the middle portion of the conductive wire is supported by a surface of the substrate.

19. The method of claim 17, wherein the electrical coupler comprises one or more redistribution layers supported by a surface of the substrate in a region between the first electronic/photonic integrated circuit and the second electronic/photonic integrated circuit.

20. The method of claim 17, wherein the substrate comprises a photonic interposer or
a packaging substrate.
